(19) United States
(12) Patent Application Publication
(10) Pub. No.: US 2009/0236312 A1
(43) Pub. Date: Sep. 24, 2009

(54) Method and apparatus for film thickness adjustment

(75) Inventor: Sergey Mishin, Goleta, CA (US)

Correspondence Address: Sergey Mishin, 7920 Winchester Circle, Goleta, CA, 93117, US

(73) Assignee: Advanced Modular System, Inc.

(21) Appl. No.: 12/077,678

(22) Filed: Mar. 21, 2008

(51) Int. Cl. H01L 21/3065

(52) U.S. Cl. 216/66; 156/345.15

(57) ABSTRACT

An ion source is used to adjust film thickness uniformity. Voltage is adjusted based on the film thickness to remove material on thicker parts of the substrate while removing almost no material on the thinner part of the substrate. Special procedure is used to obtain virtually uniform film without reducing minimum thickness on a substrate. Source calibration is used to maintain precise etch rate control. Film thicknesses can be adjusted to less than 0.5 nanometers uniformity.

### FIELD OF INVENTION

The present invention pertains to the field of film thickness adjustments by the means of the DC powered ion source. More particularly, this invention relates controlling ion source in such a manner as to only remove thicker portion of the film without reducing the thinner portion of the film appreciably.

### BACKGROUND OF THE INVENTION

Ion sources have been used for etching films for many decades. Ion sources generally use RF or DC power to generate high energy ions. Typically argon is used as a source gas, although some application use xenon or reactive gases like oxygen or nitrogen. High energy ions strike substrate dislodging material on the surface. In particular, ion sources were used with masks or variable apertures to selectively remove film from desired areas for many applications.

In the last decade several companies started using focused ion beams or ion sources with a small aperture in conjunction with a wafer movement to adjust film thickness uniformity. The amount of material removed on the surface is roughly proportional to the power applied to the source and the time under the source. Most commercially manufactured systems move substrate under RF powered source at variable speeds of up to 50 cm/second and constant power. Roth&Row Application Note January 2007 “IonScan 800—Ultra-precise film thickness trimming for Semiconductor Technology” by M. Zeuner, M. Nestler, D. Roth describes such system in great detail. As long as film thickness changes gradually, speeds can be easily adjusted to produce great improvements in film uniformity. Unfortunately some films display uniformity patterns that have the thickest and the thinnest point within a very short distance from each other. Since acceleration is limited by mechanical components it is very hard to go from maximum speed to minimum speed instantly. Typically in order to improve uniformity on such wafers, thin spots on the substrate are etched as well as thick spots and final result usually shows significant thickness loss in the thinnest part of the substrate, and the higher gradient of non-uniformity the more materials should be removed from the thinnest areas.

RF powered ion sources are very stable at given power, but take a couple of seconds to stabilize at a given power level in either power or voltage control mode. DC powered ion sources that use power control suffer from the problem that high voltage power supplies can't control power as quickly as they control voltage. Unfortunately same voltage can produce different power due to very small fluctuations in the system vacuum, pressure or background noise. A problem with running in variable voltage mode is that if the voltage is dropped too low on part of the substrate, it doesn't always come back to the same power at the other part of the wafer requiring a higher voltage. In order to be able to run in voltage control mode a special procedure is required.

Software must analyze film thickness wafer map and determine how to process the substrate to obtain the best film thickness uniformity, yet operate in the stable and repeatable regime. The invention described below allows user to improve film thickness on the substrates without loosing any significant amount of material in the thinnest part of the film.

### SUMMARY OF THE INVENTION

It is generally advantageous for many applications to produce films that have very uniform thickness. For some applications such as microwave filters it is important to have uniformities controlled to under 0.5 nm. These applications are very cost sensitive. Parts are generally as small as 0.5 mm on a side but cost only couple of cents. For this reason a machine that can adjust film thickness uniformity has to be relatively inexpensive and should be able to process a substrate fairly quickly. An improved DC ion source based apparatus has been developed that provides ability to improve film thickness uniformity without losing film in the thinnest part.

In a preferred embodiment of the present invention, an apparatus employing DC ion source with a beam diameter of 5 mm is disclosed. Calibration of voltage vs. power is performed on an appropriate material before each thickness adjustment.

If the film thickness non-uniformity is too great to allow single pass adjustment, software selects optimum conditions to first remove thickest points on the substrate, then finish the uniformity adjustment in one or more passes through the system to obtain the best thickness uniformity. Other features and advantages of the present invention will be apparent from the detailed description that follows.

### BRIEF DESCRIPTION OF THE DRAWINGS

The present invention is described with respect to particular exemplary embodiments thereof and reference is accordingly made to the drawings in which:

FIG. 1 shows the power ion source based apparatus according to the present teachings;

FIGS. 2 shows 3-Dimentional views of apparatus in one embodiment;

FIG. 3 shows an example of a calibration curve on a insulating film vs. on metal film.

FIG. 4 shows example of the film thickness uniformity change after two pass adjustment in the apparatus.

FIG. 5 demonstrates different power obtained under the same conditions if power is dropped to zero and turned back on at different voltages.

FIG. 6 shows etch rate vs. ion source power for different process conditions.

FIG. 7 shows voltage vs. power for different process conditions.

### DETAILED DESCRIPTION OF THE PREFERRED EMBODIMENT

As described herein, it is generally advantageous to be able to adjust film thickness uniformity after the film is deposited. It is sometimes very difficult if not impossible to obtain thickness uniformity required for some applications. For example, the best uniformity obtained on the best sputtering systems is about 1 to 2% full range. For some microwave filter applications the full range requirement is 0.1%.

Film thickness uniformity may be adjusted by a focused ion beam (FIB) or an ion source with RF power source. Even though FIB can provide the required uniformity, equipment costs on the order of $1M or more and can only adjust about 100 to 200 wafers per month due to the small size of its ion beam (generally 0.01 mm to 0.5 mm). Typical ion source with RF power source must operate in a fixed power mode with substrate moving at variable speeds to provide uniformity adjustment. Even though it can produce similar improvement in uniformity, the thinnest part of the film is also etched during the process. If this area is already close to the minimum allowable thickness, it becomes unusable.

In a preferred embodiment of the present invention a DC high voltage supply is used in voltage control mode. DC high voltage power supplies typically used for ion mill operations can adjust voltage in a matter of millisecond. When the same power supply is used in a power control mode, the response time is on the order of a second. In order to illustrate the importance of the power vs. voltage control time is useful to look at an example of adjusting a substrate that has 1 millimeter (mm) size devices on a side. If the ion source moves at 500 mm/second speed in 1 millisecond it will move 0.5 mm. In 1 second it will move 500 mm. Using voltage adjustment, the change in power can be easily accomplished in a span of one device. Using power adjustment mode, it is 500 devices before adjustment is made.

Another advantage of the present invention is that when using voltage control, power can be adjusted based on a calibration curve in a few milliseconds. This allows power drop from a maximum power to a zero level in a few milliseconds. Standard systems that use constant power and adjust speed of the substrate motion under the ion source can not reduce removal rate from maximum to zero instantly. RF powered sources take several seconds to stabilize at a given power, limiting their application to a constant power variable substrate speed applications. R. Aigner “Corrective Actions to Meet Extreme Tolerance Requirements for Thin Films: How to make peace with your deposition tools” describes such RF powered sources. He acknowledges that such systems have to operate at either unacceptably low power or a significant amount of material will be removed in a thin part of the substrate. It is especially difficult for such systems to improve uniformity on a substrate with very large thickness gradient. In cases where the thinnest and the thickest part of the film are close to each other the thinnest point may have to be reduced by the same amount as the difference between thinnest and thickest point on the substrate. Due to the complexity of the vacuum compatible motion devices that allow ultra fast acceleration from low to high speed, they are very expensive and very large. In the present invention, power drops to zero resulting in virtually no loss in the thinnest spot. Since the substrate moves at constant speed, linear drive devices are very small and inexpensive, allowing for very low cost machine.

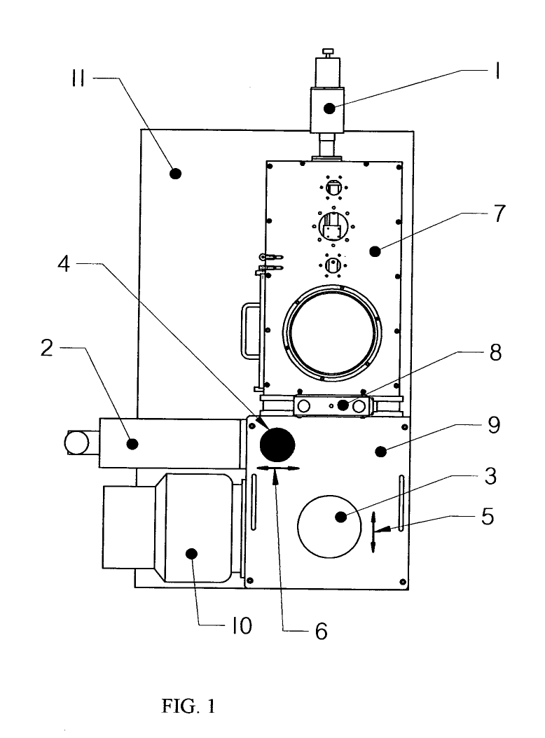

FIG. 1 shows a top view of the preferred embodiment. Process module 9 that contains an ion source 4 driven by a linear motion drive 2 in the x-direction as indicated by arrow 6. Base chamber vacuum is in 1E-6 torr range accomplished by a combination of turbo-pump 10/dry backing pump (not shown here). A linear drive motor 1 moves a substrate 3 in y-direction perpendicular to the ion source travel indicated by arrow 5. Substrate is loaded into small vacuum chamber called load-lock 7. This chamber is pumped by a dry vacuum pump to 1E-3 torr range. Then the gate valve 7 separating process module 9 and load-lock 7 is opened. Pressure is raised into 2E-5 to 8E-5 torr range by injecting argon gas into the chamber via mass flow controller. Film thickness uniformity map is loaded into the system computer. Computer selects voltage levels as wafer moves under the source in y-direction. After wafer completes a scan under the source, source moves in x-direction by an increment of between 0.5 mm to 2.5 mm. This increment size is dictated by the size of the device. In general the increment size is the same as the size of the device. If the increment is too large, some devices will get incorrect thickness adjustment. If the increment size is too small it will take too long to process the substrate.

Ion source beam size is dictated by the device size on the substrate and the size of the substrate. For the typical substrate size of 150 mm to 200 mm diameter, beam size should be greater than 2 mm. If the beam size is smaller than 2 mm it will take too long to process substrate to be practical. This eliminates focused ion beam (FIB) as a practical device for this application, if the device size on the substrate is between 0.5 mm to 2 mm on a side. If the beam size is too large, it will be impossible to make sharp changes in the etch rate between adjacent parts of the substrate. With device sizes between 0.5 mm to 2.5 mm on a side the maximum practical beam size is between 2 mm to 10 mm.

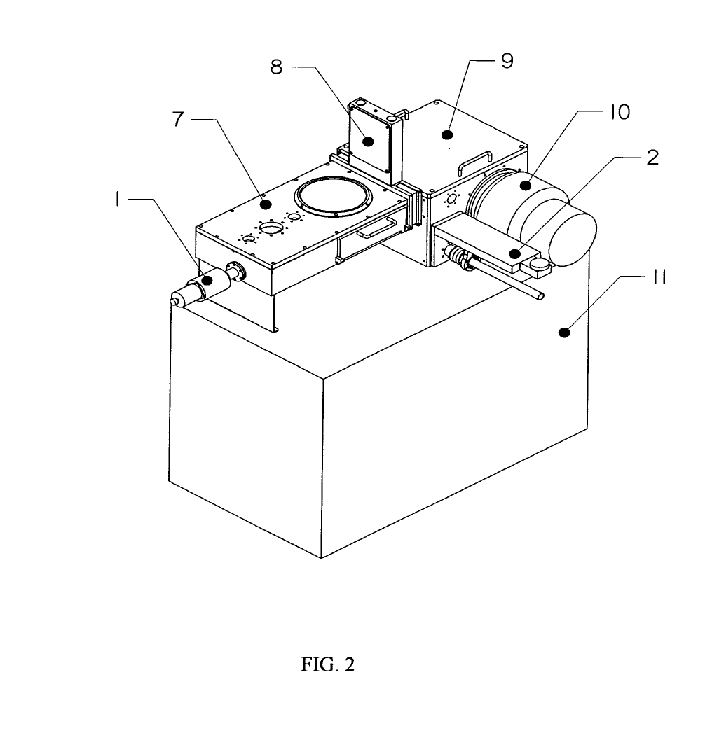

FIG. 2 shows 3-Dimentional view of the preferred embodiment. Both loadlock 7 and process module 9 are mounted on top of the frame 11. Since the speed of substrate/ion source movement is constant, a very simple and inexpensive linear drive motion system can be used. DC ion source is basically a reverse of a sputtering magnetron. This allows for a very simple and compact apparatus.

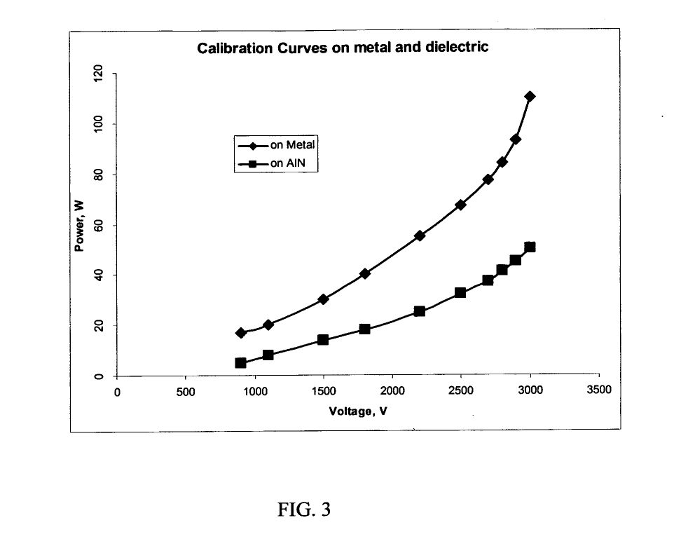

FIG. 3 shows an example of a calibration curve on an insulating film vs. a metal film. As can be seen from the graph, both curves are similar. Using a standardize calibration pad allows for very repeatable operation.

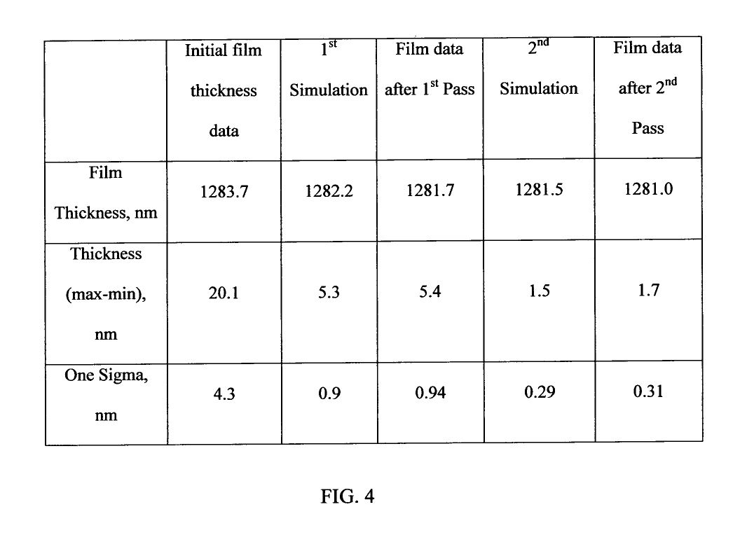

FIG. 4 shows example of the film thickness uniformity changes after two pass adjustment in the apparatus. The first pass improves standard deviation by a factor of five, removing the thickest spots on the substrate. It shows initial thickness uniformity, measured and simulated results after the first thickness adjustment. Gas flow is adjusted to allow for the regime that goes to 60 watts. Program automatically selects zero power for the points below points that would require voltages below 800 Volts to adjust the thickness. The second pass uses lower gas flow that allows for lower power operation with great control. Since calibrations are performed before each pass, a new voltage vs. power curve is generated automatically at this gas flow. The minimum power is set to zero to obtain the total erosion of material in the thinnest part of the film close to zero. The film non-uniformity is reduced to under 0.3 nanometers one sigma from the original non-uniformity of 20 nanometers. Two pass operation allows user to keep the ion source voltage in a tightly controlled regime that allows power operation from zero to the maximum power. FIG. 4 shows measured and simulated results after the second pass adjustment.

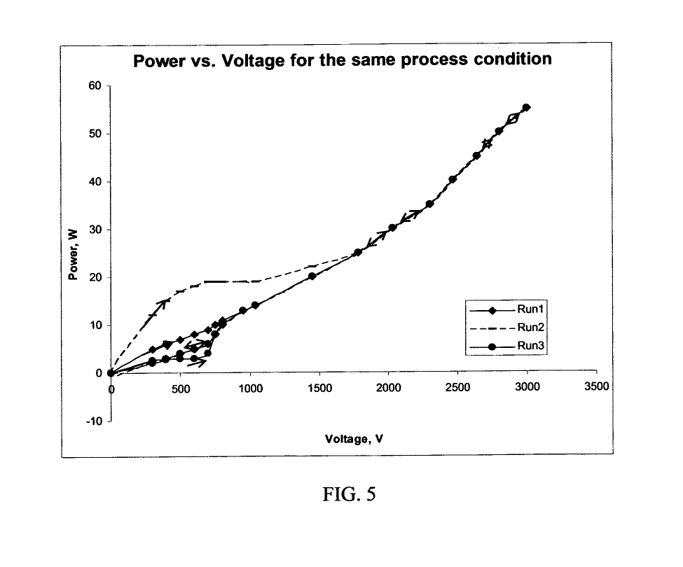

FIG. 5 demonstrates different power obtained under the same conditions if the voltage is dropped to below 800 Volts and then turned back to a higher voltage. If the voltage is dropped to a level to get close to a zero power and then turned on at above 800 Volts, power vs. voltage curve is stable and is the same compare to the curves obtained if the power is turned on at higher voltages all the way up to 3000 Volts. If voltage is dropped to below 800 Volts and when turned on at low voltage, it can be seen that at the same voltage there are drastically different power is obtained. This is a critical point when operating the existing apparatus. Since power is dropped to zero at the points where the film is the thinnest, when the voltage is increased in the next moment it is possible to get drastically different power than obtained under the calibration conditions. This will lead to poor uniformity adjustment. In order to avoid this variable power vs. voltage behavior, software checks the entire film thickness uniformity map to determine if any points will require change in voltages that will potentially produce this instability. Then the software determines maximum thickness that can be adjusted with voltage set above 800 volts. Points with thickness below this level are automatically set to receive zero power. Software simulates the new film thickness uniformity map obtained with voltage running in the calculated range. Using this map, software runs the next adjustment. Typically only two to three thickness adjustments are necessary to obtain uniformity improvement to below 0.5 nm standard deviation.

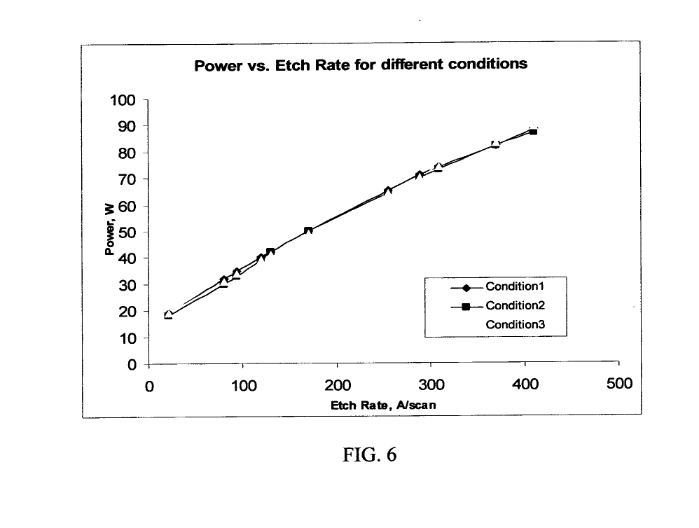

FIG. 6 shows etch rate vs. ion source power for different process conditions. Condition 1 is at 2E-5 torr pressure. Condition 2 is at 7E-5 torr pressure. Condition 3 is at 2E-5 torr pressure after a thirty minute warm-up etch. It is clear that for this ion source used in the preferred embodiment, etch rate is only dependent on power. This makes it easier for the software program to calculate optimum power levels at different process conditions.

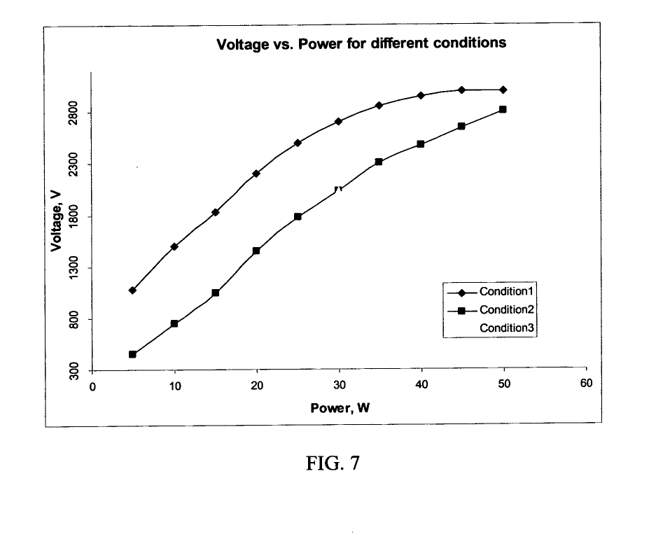

FIG. 7 shows voltage vs. power for different process conditions. Condition 1 is at 2E-5 torr pressure. Condition 2 is at 7E-5 torr pressure. Condition 3 is at 2E-5 torr pressure after a thirty minute warm-up etch. In the present embodiment, higher power (at the same voltage level) is obtained at higher gas flow. Because the apparatus in the present embodiment uses constant pumping speed, higher gas flow leads to higher gas pressure. Current is proportional to the ion density, therefore, higher pressure leads to higher current and higher power at the same voltage level. There is also an appreciable difference in power level (at the same voltage) when system is just turned on (Condition 1) and after a significant warm-up (Condition 3). For repeatable operation, it is advisable to run the system with a warm-up before first adjustment.

The mechanism described in this invention is particularly advantageous for the manufacture of devices that require very tight film thickness uniformity control. For application to the microwave cellular phone application, as an example, filters are constructed on a silicon wafer as individual die about 1 by 1 millimeter square. A 150 mm diameter wafer may host over ten thousand individual filters, all of which are preferably within approximately 0.1% of the nominal center frequency. The thickness all layers determines the frequency of the filter. Uniformity of the films across wafer must be better than 0.1% one sigma for the filter yield to be 80%. If uniformity degrades to 1%, yield will be proportionately reduced to 10%, rendering commercial manufacturing of these filters problematic. Certain percentage of the wafers has uniformity profiles that have a large change in thickness over a short distance. If such wafers have the thinnest area that is close to the minimum thickness, these wafers can't be adjusted by an ion mill that uses constant power and variable speed. The invention described here is a perfect solution for such problems because it allows to increase die yield to the maximum level even on such difficult wafers.

### SCOPE OF THE INVENTION

The foregoing detailed description of the present invention is provided for the purposes of illustration and is not intended to be exhaustive or to limit the invention to the precise embodiment disclosed. Accordingly, the scope of the present invention is defined by the appended claims.

We claim:

1. An apparatus comprising:
a vacuum processing chamber;
a DC powered ion source capable of being moved in at least one direction;
a substrate motion stage capable of being moved in at least one direction;
power calibration pads;
a computer controlled high voltage power supply.

2. The apparatus of claim 1, employs a mechanism to move the substrate in either x or y direction at a constant speed.

3. The apparatus of claim 1, employs a mechanism to move the DC powered ion source in either x or y direction at a constant speed.

4. The apparatus of claim 1, calibrates the ion source on a metal calibration pad for the metal based films and on an insulator pad for the dielectric films.

5. A method comprising of:
providing a processing chamber having a substrate and a DC ion source positioned therein;
exposing substrate to the varying amount of ion bombardment based on the substrate film thickness uniformity map.

6. The method of claim 5, further comprising running the ion source in a voltage controlled mode.

7. The method of claim 5, further comprising of calibrating power vs. voltage before processing each substrate.

8. The method of claim 5, further comprising of automatically reducing power to zero if the required voltage is below 800 Volts.
